(19) United States
(12) Patent Application Publication
(10) Pub. No.: US 2003/0020551 A1
(43) Pub. Date: Jan. 30, 2003

(54) Electric filter with blocking behavior for a predetermined rejection frequency

(75) Inventor: Johann Henkel, Rosenheim (DE)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics GmbH, Grasbrunn (DE)

(21) Appl. No.: 10/187,401

(22) Filed: Jun. 28, 2002

(30) Foreign Application Priority Data
Jun. 28, 2001 (DE) 101 31 224.5

(51) Int. Cl. H03L 7/00

(52) U.S. Cl. 331/18

(57) ABSTRACT

An electric low-pass filter with blocking behavior for a predetermined rejection frequency, comprising a series connection including a FIR filter and an IIR filter, with the parameters of the FIR filter being matched in essence with respect to the blocking behavior at the rejection frequency and the parameters of the IIR filter being matched in essence with respect to the low-pass behavior. It is possible with such a filter to obtain good low-pass behavior with very high attenuation of the frequency to be rejected, with relatively low circuit expenditure and high stability with respect to oscillation tendency.

### BACKGROUND OF THE INVENTION

1. Field of the Invention

The invention relates in general to electric filters and, more particularly, to electric filters for blocking predetermined rejection frequencies.

2. Description of the Related Art

Electric filters with blocking behavior for a predetermined rejection frequency are necessary, for example, as loop filters for PLL circuits. A basic circuit diagram of a PLL circuit is shown in FIG. 4 and comprises a mixer stage 11 fed on the one hand with a reference frequency and on the other hand with an oscillator frequency from a controllable oscillator (NCO: Numerically Controlled Oscillator) 13. The mixed product is fed to oscillator 13 via a loop filter 15. The mixed product of mixer stage 11 contains a sum frequency and a differential frequency which are formed by the sum and the difference, respectively, of the two frequencies supplied to mixer stage 11. In practical application, and in particular in the latched state of the PLL circuit, the sum frequency is twice as high as the reference frequency.

Loop filter 15 has two functions to perform. First, it is supposed to block or reject the sum frequency, and secondly it is to smooth or average the differential frequency so that an appropriate frequency control quantity can be supplied to oscillator 13.

So far, either an analog LC filter or an IIR filter, with IIR standing for Infinite Impulse Response, have been used as a loop filter. The basic structure of an IIR filter is illustrated in FIG. 2 and is known per se. Such a filter has n timing elements or delay stages Z⁻¹, a plurality of coefficient stages a1-an and b0-bn as well as two summation elements. Due to its feedback structure, the IIR filter has an undesired oscillation tendency. For obtaining both the desired low-pass behavior and the blocking behavior, such an IIR filter must be composed with a relatively large number of stages, which does not only require a correspondingly high number of electronic components, but also increases the oscillation tendency.

Another known filter type is the FIR filter, with FIR standing for Finite Impulse Response. The basic structure of a FIR filter is illustrated in FIG. 3. In case of this filter, there is a number of timing or delay elements Z⁻¹ connected in series, the necessary coefficients are generated using multipliers C0-Cn, and the output signals of the multipliers are combined to form an output signal in a summation stage. Due to the fact that such a filter has no feedback structure, there are no problems involved as regards oscillation tendency. It is indeed possible with such a filter to obtain a good blocking behavior for the rejection frequency, i.e., the sum frequency. However, for a satisfactory low-pass behavior, such a filter would have to be composed with a relatively large number of filter stages, involving correspondingly high expenditure.

A digital FIR notch filter with a construction of the type illustrated in FIG. 3 is known from JP 04-249913 AA, with this filter serving to eliminate an undesired signal.

The document EP 0 714 201 A2 describes a digital phase locked loop used for carrier recovery in a signal processor system for digital television signals. The phase locked loop comprises, among other things, a phase detector, a voltage-controlled oscillator and a notch filter in the form of a FIR filter. The FIR filter produces two notches serving to reject the picture carrier frequency and the chrominance carrier frequency.

### BRIEF SUMMARY OF THE INVENTION

Embodiments of the invention make available a filter which, with relatively low circuit expenditure and high stability with respect to oscillation tendency, displays a good low-pass behavior with high attenuation of the rejection frequency and thus is particularly well suited as a loop filter for a PLL circuit.

A low-pass filter according to an embodiment of the invention is characterized by a series connection including a FIR filter and an IIR filer, with the parameters of the FIR filter being matched in essence with respect to the blocking behavior at the rejection frequency and the parameters of the IIR filter being matched in essence with respect to the low-pass behavior.

In an application as loop filter for a PLL circuit, it is sufficient in case of a low-pass filter according to an embodiment of the invention to employ one FIR filter with three timing elements and one IIR filter with one timing element. Such a filter displays both good low-pass behavior and good blocking behavior for the rejection frequency with relatively low circuit expenditure.

### BRIEF DESCRIPTION OF THE SEVERAL VIEWS OF THE DRAWING(S)

Embodiments of the invention will now be described, by way of example only, by referring to the annexed drawings, wherein:

FIG. 1 shows a structure of a filter according to the invention;

FIG. 2 shows a structure of a known-per-se IIR filter;

FIG. 3 shows a structure of a known-per-se FIR filter;

FIG. 4 shows a structure of a known-per-se PLL circuit;

FIG. 5 shows a basic circuit diagram of a filter according to the invention;

FIG. 6 shows an attenuation curve of a FIR filter;

FIG. 7 shows an attenuation curve of an IIR filter; and

FIG. 8 shows an attenuation curve of a filter according to the invention.

### DETAILED DESCRIPTION OF THE INVENTION

In case of use of a low-pass filter according to embodiments of the invention as a loop filter in a PLL circuit, the sum frequency, namely twice the reference frequency, is kept away from the oscillator with very high attenuation, whereas the control quantity supplied to the oscillator exhibits good smoothing or averaging due to the low-pass filtering by the loop filter.

Due to the low number of necessary timing elements, a filter according to the invention has a low time constant, resulting in a short transient time of the filter and, in case of use thereof as a loop filter of a PLL circuit, in a short latching time of the PLL circuit.

For obtaining the same blocking attenuation for the rejection frequency as with an IIR filter used conventionally for loop filters of PLL circuits, there is required considerably less circuit expenditure and thus expenditure in terms of costs.

The order of arrangement of FIR filter and IIR filter in the series connection of a filter according to the invention can be chosen in arbitrary fashion.

Due to the fact that there are two filter types connected in succession according to the invention, one thereof being suited more for low-pass filtering and the other one thereof being suited more for rejection frequency attenuation, it is possible in case of each one of these two filters to concentrate on the optimization with respect to its function, thus allowing a very good overall filter behavior to be obtained. The IIR filter may be optimized with respect to low-pass filtering, since it is not necessary at the same time to provide for an attenuation success as regards the rejection frequency, whereas the FIR filter may be optimized with respect to the attenuation behavior at the rejection frequency, as no attention has to be paid to the low-pass filtering success. Due to the fact that each one of these two filters has to be dimensioned and optimized with respect to only one of these two filter aspects, each one of these two filters can dispense with high circuit expenditure.

A filter according to the invention is suitable in all applications requiring at the same time good low-pass behavior and high blocking attenuation for a rejection frequency.

The invention will now be elucidated in more detail by way of embodiments.

In the following, an embodiment of a filter according to an embodiment of the invention will be considered which is suitable in particular as a loop filter for a PLL circuit having a sum frequency of 38 KHz.

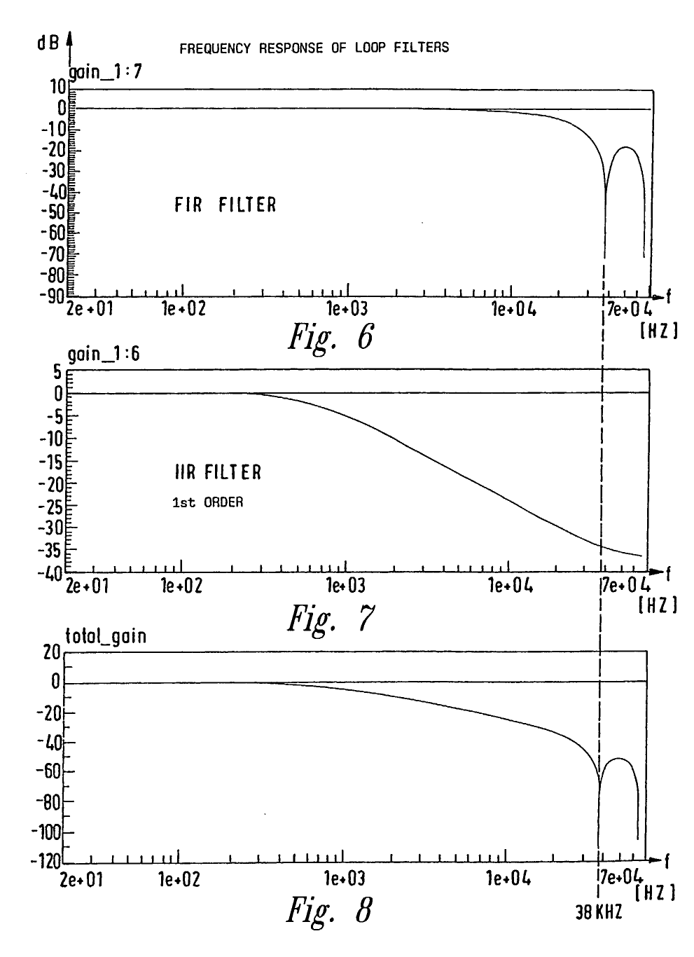

The attenuation behavior shall be considered first by way of FIGS. 6 and 7, which can be obtained using only one FIR filter or only one IIR filter. As illustrated in FIG. 6, the FIR filter is suited to achieve narrow-band and high attenuation of the sum frequency when one of the zero positions of the FIR filter is placed at sum frequency. As can be seen from FIG. 6, there is virtually no low-pass filtering present up to the range near the sum frequency.

The attenuation behavior of the IIR filter illustrated in FIG. 7 exhibits a pure low-pass attenuation behavior. Notch-shaped blocking attenuation locations (also referred to as notches) would be possible only with additional circuit expenditure and a disadvantageous prolongation of the filter group transit time.

The attenuation behavior of a filter according to the invention illustrated in FIG. 8, comprising a series connection of a FIR filter and an IIR filter, exhibits high rejection frequency attenuation at sum frequency and good low-pass filter behavior below sum frequency.

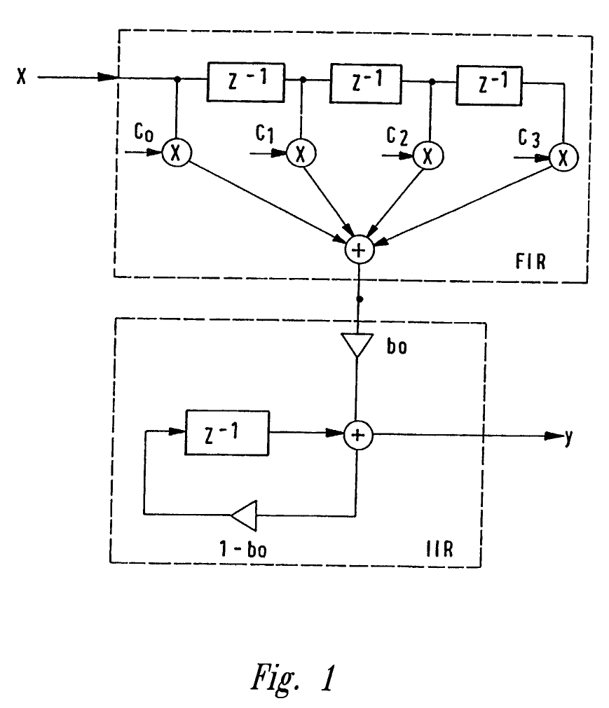

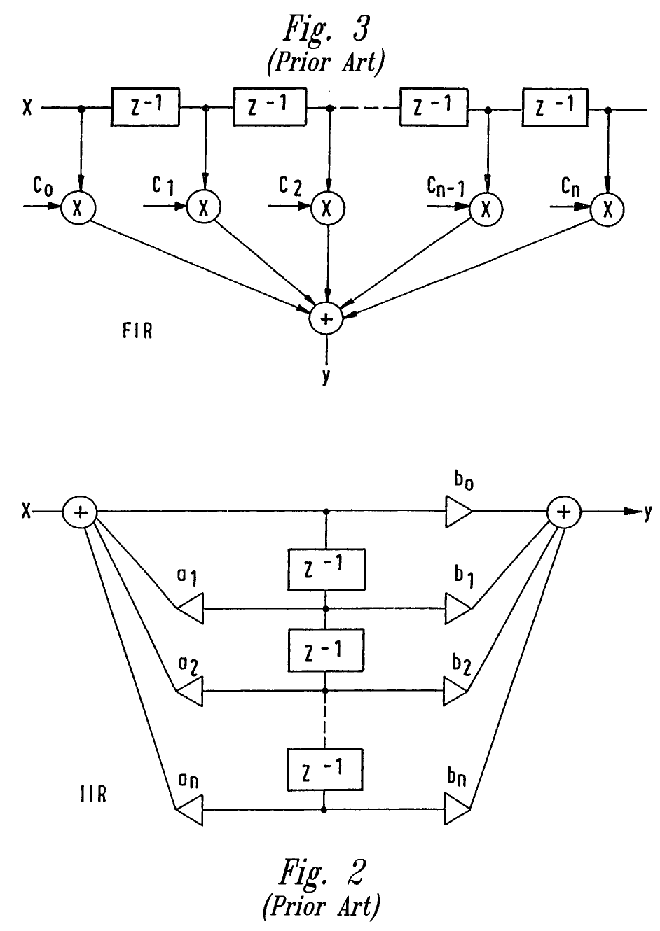

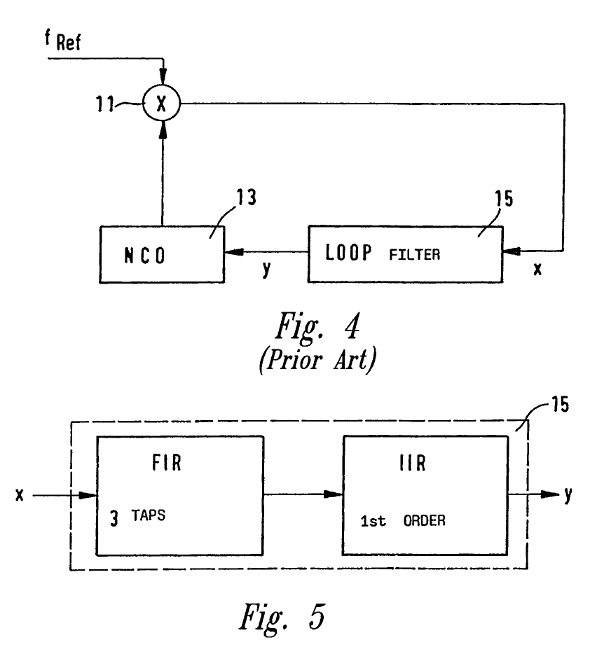

This is achieved with a filter having the structure shown in FIG. 1. With respect to the FIR filter component, it is sufficient to use three delay elements Z⁻¹, four multiplier circuits, marked X, and one summation element, marked +. As regards the IIR filter component, it is sufficient to have one single stage, i.e., an IIR filter of first order comprising merely one delay element Z⁻¹, two factor multipliers, marked b0 and 1−b0, and one summation element. Thus, for the entirety of the filter, there are required only four delay elements, so that the overall filter has a short total time constant and a circuit expenditure that is comparatively low with respect to conventional filter solutions using one filter type only.

In the FIR filter component, the zero position leading to the high blocking attenuation at sum frequency can be adjusted very well using the parameters C0-C3. The averaging or smoothing function of the IIR filter component can be adjusted by way of the factors b0 and 1−b0.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. An electric low-pass filter with blocking behavior for a predetermined rejection frequency, comprising a series connection including a FIR filter and an IIR filter, with parameters of the FIR filter being matched in essence with respect to the blocking behavior at the rejection frequency and the parameters of the IIR filter being matched in essence with respect to the low-pass behavior.

2. The electric low-pass filter according to claim 1,
wherein said FIR filter is composed with three time elements and said IIR filter is composed with one time element.

3. The electric low-pass filter according to claim 1 wherein the parameters of the FIR and IIR are matched to use the electric low-pass filter as a loop filter of a PLL circuit.

4. A PLL circuit comprising:
a reference frequency source,
an oscillator having an oscillator frequency, the oscillator being controllable with respect to the oscillator frequency,
a mixer stage and
a loop filter comprising a series connection including a FIR filter and an IIR filter, said loop filter connected between said mixer stage and said oscillator, said mixer stage having a reference frequency and an oscillator frequency supplied thereto, said mixer stage generating a sum frequency from said reference frequency and said oscillator frequency as well as a differential frequency from said reference frequency and said oscillator frequency, said oscillator having the output signal of the loop filter supplied thereto as control quantity for the oscillator frequency, said FIR filter being designed for rejection of the sum frequency and said IIR filter being designed for smoothing said control quantity.

5. The PLL circuit of claim 4 wherein said FIR filter includes a zero position associated with high blocking attenuation at the sum frequency, the zero position being adjustable through four parameters and the smoothing of said IIR filter being adjustable through two factors.

6. A system comprising:
a reference frequency source;
an oscillator;
a mixer; and
a loop filter including a FIR filter and an IIR filter coupled in series, the FIR filter having parameters substantially matched with respect to a rejection frequency and the IIR filter having parameters substantially matched with respect to a low-pass behavior, the loop filter being coupled between the mixer and the oscillator, the mixer stage being coupled with the reference frequency source and the oscillator, and the oscillator being coupled to loop filter.

7. The system of claim 6 wherein said FIR filter includes a plurality of delays being coupled together in series, and a plurality of multipliers, each multiplier being coupled to a delay and said plurality of multipliers being coupled to a summation stage.

8. The system of claim 7 wherein said plurality of delays consist of three delays.

9. The system of claim 6 wherein said IIR filter includes an input, an output, a summation element being coupled to the output, a first coefficient stage being coupled between the input and the summation element, a first pair of coefficient stages being coupled between the input and the summation element in parallel with the first coefficient stage, and a delay being coupled to the first coefficient stage and the coefficient stages of the first pair.
